(19) United States
(12) Patent Application Publication
(10) Pub. No.: US 2014/0332961 A1
(43) Pub. Date: Nov. 13, 2014

(54) Cu/CuMn BARRIER LAYER AND FABRICATING METHOD THEREOF

(71) Applicant: National Cheng Kung University, Tainan City (TW)

(72) Inventors: Wen-His Lee, Kaohsiung City (TW); Chia-Yang WU, Tainan City (TW)

(73) Assignee: National Cheng Kung University, Tainan City (TW)

(21) Appl. No.: 14/075,866

(22) Filed: Nov. 8, 2013

(30) Foreign Application Priority Data
May 10, 2013 (TW) 102116797

(51) Int. Cl. H01L 21/768; H01L 23/532; B32B 15/01

(52) U.S. Cl. CPC H01L 21/76858; B32B 15/01; H01L 23/53238
USPC 257/751; 428/675; 438/653

(57) ABSTRACT

In the present invention, the pure Cu film is deposited on the CuMn film and the Mn atoms are induced to diffuse within the dielectric layer. The barrier properties of this self-forming barrier are sensitive to the thickness, the annealing temperature, the annealing time and the impurity concentration of itself. The bi-layer structure reduces the resistance of the barrier and improves the surface morphology during the electroplating process because the Mn atoms will be more easily corroded and oxidized in sulfuric acid with respect to the Cu. After annealing, the thermal stability and the barrier properties of the Cu/CuMn films is better than either single Cu film or single CuMn film.

### CROSS REFERENCE TO RELATED APPLICATION

The present invention claims the benefits of priority from the Taiwanese Patent Application No. 102116797, filed on May 10, 2013, the contents of the specification of which are hereby incorporated herein by reference.

### FIELD OF THE INVENTION

The present invention relates to a semiconductor structure fabricating method and a device thereof. In particular, it relates to a semiconductor metal barrier structure fabricating method and a device thereof.

### BACKGROUND OF THE INVENTION

The self-forming barrier technique relates to the doping of other metals such as titanium, aluminum and manganese into the Cu metal material. These dopants are not only for creating an anti-diffusion layer with good thermal stability but effectively suppressing the entire resistivity. Hence, the materials which can be doped must have the following characteristics: (1) Doping materials have to be immiscible with the Cu and applicable for the sputter scheme for growth so as to ensure that the compositions of the thin film such as aluminum, manganese, tin and titanium are under control during the film-sputtering process; (2) The diffusion velocities of the dopants must be faster than that of the Cu so as to effectively form the barrier layer at the interface of the dielectric layer. Some materials with high thermal stabilities do not meet this requirement because the diffusion velocities thereof are not fast enough. These materials, for example, Ta, Wu and Mo, cannot form the barrier layer at the interface before the Cu drills into the dielectric layer; (3) The smaller free energy of oxide is better (larger negative value) so that it ensures there are enough driving forces for the dopants to form the barrier layer within the interface. However, the free energy thereof can only be less small than that of the silicon dioxide to avoid the circumstance that the dopants still drill into the dioxide layer after the barrier layer has been formed; and (4) The coefficient of the free energy has to be approximate to 1 or larger than 1 when the dopants and the Cu are in a liquid environment so as to help the dopants move into the interface.

In the development of the copper metallization, there are many concerning issues including: (1) aluminum can form the passivation layer but copper cannot. The plated copper film can easily be oxidized and eroded by humidity in the atmosphere, which affect, the stability of the conductivity of the metal lead; (2) In a low temperature like 200° C., copper reacts with silicon or silicon-based material to form a chemical compound such as Cu₃Si in the integrated circuit (IC) structure, which can cause the failure of components; (3) The adhesion between copper and the dielectric layer is weak, with the result being that the mechanical strength of the thin film structure in the IC is insufficient; (4) Copper atoms have the characteristic of fast diffusion. In the circumstance of electric field acceleration, copper can penetrate the dielectric and diffuse quickly. In particular, for silicon-based materials, once the Cu atoms diffuse into silicon-based materials, a deep level acceptor will be drawn in and cause a degradation and a failure of the characteristics of the components; (5) The vapor pressure of the halogen gas of copper in the plasma is too low to apply a dry etching scheme such as reactive ion etching to fabricate delicate patterns of circuits.

There is a need to solve the above deficiencies/issues.

### SUMMARY OF THE INVENTION

In accordance with the first aspect of the present invention, a method for fabricating a semiconductor structure is disclosed. The method includes providing a substrate; forming a trench in the substrate; conformably forming a copper-manganese alloy layer on the trench; conformably forming a copper metal layer on the copper-manganese alloy; and annealing the copper-manganese alloy layer and the copper metal layer to form a barrier.

In accordance with the second aspect of the present invention, a semiconductor structure is disclosed. The semiconductor structure includes a substrate; an alloy layer having a first metal formed on the substrate; a metal layer having a second metal formed on the alloy layer; and a barrier formed between the alloy layer and the metal layer.

In accordance with the third aspect of the present invention, a barrier structure is disclosed. The barrier structure includes an alloy layer having a first metal, wherein the first metal is a transition metal; and a pure first metal layer conformably formed on the alloy layer.

### BRIEF DESCRIPTION OF THE DRAWINGS

A more complete appreciation of the invention and many of the attendant advantages thereof are readily obtained as the same become better understood by reference to the following detailed descriptions when considered in connection with the accompanying drawings, wherein:

FIG. 1 is a schematic diagram of an initial structure of the present invention in accordance with the present invention;

FIG. 2 is a schematic diagram of an initial structure of the present invention in accordance with the present invention;

FIG. 3 is a schematic diagram of an initial structure of the present invention in accordance with the present invention;

FIG. 4 is a schematic diagram of an initial structure of the present invention in accordance with the present invention;

FIGS. 5-7 are an embodiment of a Cu/CuMn dual barrier layer of the present invention in accordance with the present invention;

FIGS. 8-9 are an embodiment of a copper metallization of the present invention in accordance with the present invention;

FIGS. 10a-11e are pictures of barrier effect rendered by the bi-layer structure of the present invention in accordance with the present invention.

### DETAILED DESCRIPTION OF THE PREFERRED EMBODIMENT

The present invention will be described with respect to particular embodiments and with reference to certain drawings, but the invention is not limited thereto but is only limited by the claims. The drawings described are only schematic and are non-limiting. In the drawings, the size of some of the elements may be exaggerated and not drawn to scale for illustrative purposes. The dimensions and the relative dimensions do not necessarily correspond to actual reductions in practice.

It is to be noted that the term “including”, used in the claims, should not be interpreted as being restricted to the means listed thereafter; it does not exclude other elements or steps. It is thus to be interpreted as specifying the presence of the stated features, integers, steps or components as referred to, but does not preclude the presence or addition of one or more other features, integers, steps or components, or groups thereof. Thus, the scope of the expression “a device including means A and B” should not be limited to devices consisting only of components A and B.

The invention will now be described with a detailed description of several embodiments. It is clear that other embodiments can be configured according to the knowledge of persons skilled in the art without departing from the true technical teaching of the present invention, the claimed invention being limited only by the terms of the appended claims.

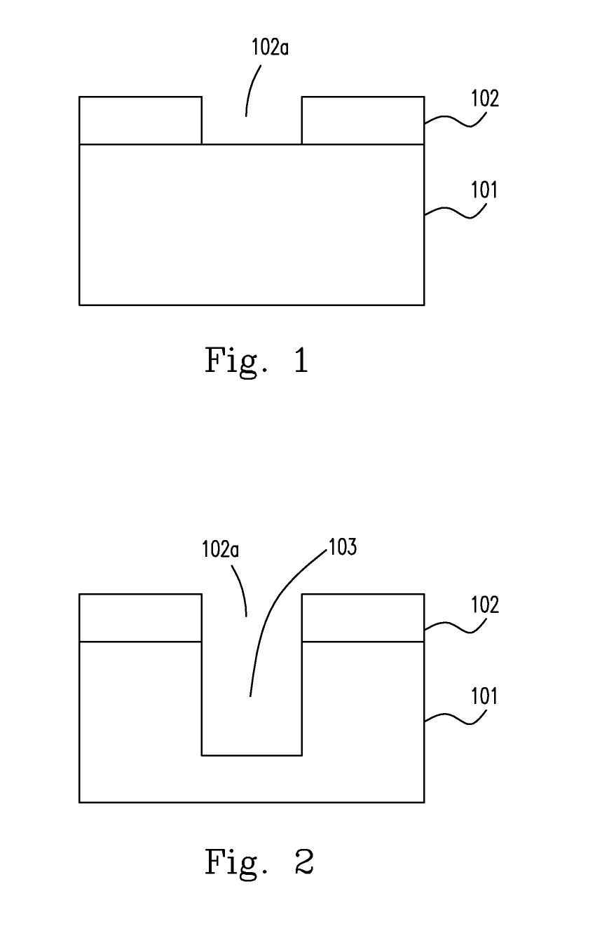

Please refer to FIG. 1 disclosing a schematic diagram of an initial structure of the present invention. The initial structure includes a substrate 101 and a first photo resist layer 102, wherein a portion of the photo resist of the first photo-resistive layer 102 is removed by a development scheme of the lithography to form a first opening 102a. Preferable materials for the substrate 101 include, but are not limited to, one of a silicon dioxide and a silicon wafer.

Preferably, the initial structure will be transformed into a dual damascene structure, wherein the dual damascene structure can be classified into a trench-first structure, a via-first structure and a self-aligned structure according to different processes. In the certain embodiments, a via-first structure is shown, but is not limited to, as an example.

Please refer to FIG. 2 disclosing a schematic diagram of an initial structure of the present invention. A first trench 103 is formed by etching downward from the first opening 102a and ceasing at a first etching stop layer (not shown) with an etching scheme which is a dry etching scheme in particular.

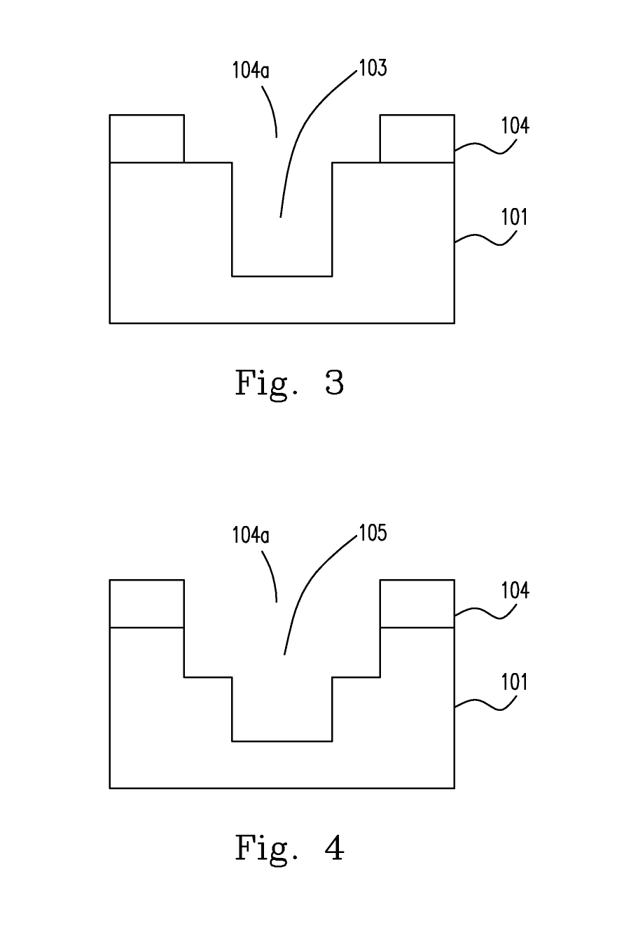

Please refer to FIG. 3 disclosing a schematic diagram of an initial structure of the present invention. First, the first photo resist layer 102 is removed in order to form a T-shaped trench. Subsequently, a second photo resist layer 104 is formed on both sides of the substrate 101, wherein there is a second opening 104a in the second photo resist layer 104. The width of the second opening 104a is larger than the width of first opening 102a.

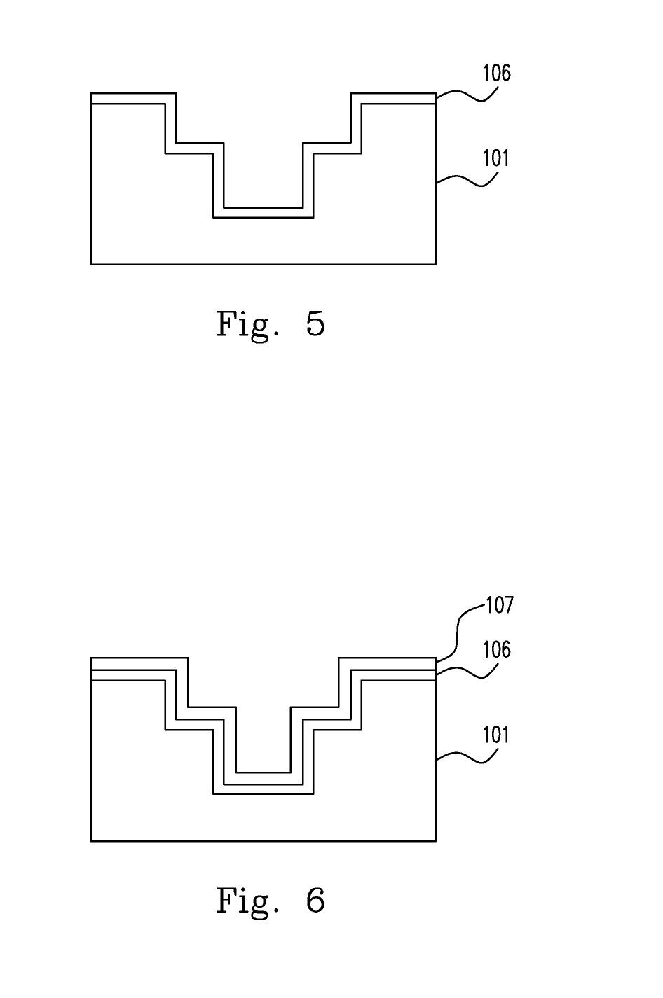

Please refer to FIG. 4 disclosing a schematic diagram of an initial structure of the present invention. A second trench 105 is formed by etching downward from the second opening 104a and ceasing at a second etching stop layer (not shown), wherein the second trench 105 is a T-shaped trench.

Preferably, the second photo resist layer 104 is removed by one of a wet stripping scheme and a dry stripping scheme.

Please refer to FIGS. 5-7 disclosing an embodiment of the Cu/CuMn dual barrier layer of the present invention. In FIG. 5, a CuMn layer 106 is formed on the substrate 101. The CuMn layer 106 can be deposited by vacuum methods such as sputtering, chemical vapor deposition (CVD), metalorganic vapour phase epitaxy (MOCVD), plasma-enhanced chemical vapor deposition (PECVD), evaporation, sublimation, electron cyclotron resonance plasma-enhanced chemical vapor deposition (ECR-PECVD) and a combination thereof.

In FIG. 6, a Cu layer 107 is formed on the CuMn layer 106 by a deposition scheme including, but not limited to, sputtering, CVD, MOCVD, PECVD, deposition, sublimation, ECR-PECVD and a combination thereof.

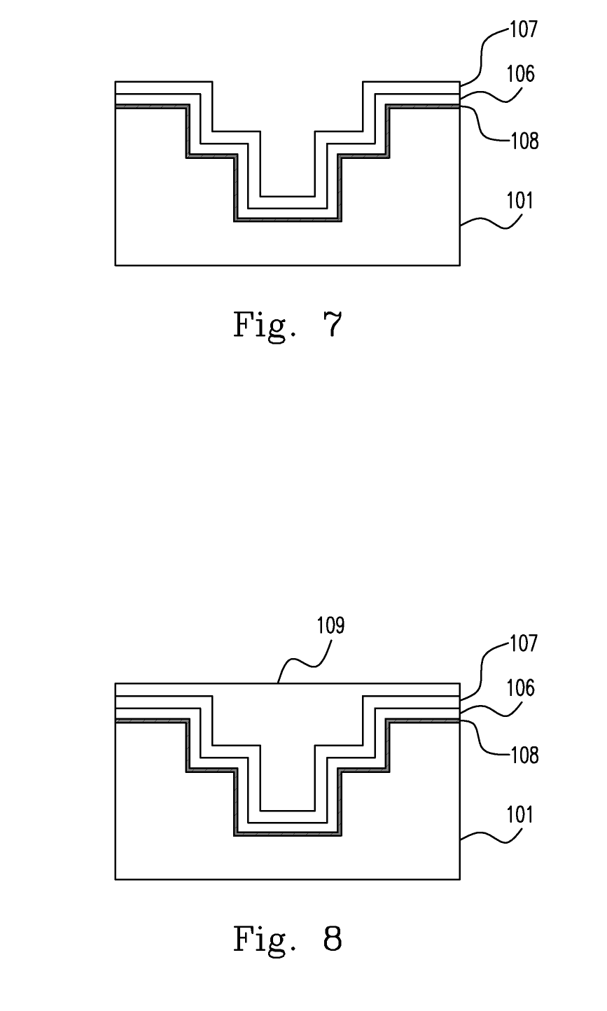

In FIG. 7, a heat treatment is applied to the substrate 101, the CuMn layer 106 and the Cu layer 107 by an annealing method such as a rapid thermal annealing scheme. During the annealing process, a barrier 108 is formed between the substrate 101 and the CuMn layer 106.

Preferably, a first width includes a width of the CuMn layer 106 and a width of the Cu layer 107. There is a first interface between the Cu layer 107 and the CuMn layer 106, and a second interface between the CuMn layer 106 and the substrate 101.

The first width is maintained at 150 nm, wherein the Cu atoms in the Cu layer 107 can restrain the Mn atoms in the CuMn layer 106 from diffusing toward the first interface, and drive the Mn atoms to diffuse toward the second interface after 30 minutes of annealing at 500° C. while the width of the Cu layer is larger than 50 nm. The residual Mn atoms in the Cu layer 107 and the CuMn layer 106 can be reduced thereby. If the width of the Cu layer is less than 50 nm, the migration of the Mn atoms toward the first interface cannot be restrained, and there are some areas of the first interface existing in a CuMn state.

Preferably, the first width is maintained at 150 nm but the width of the CuMn layer and the width of the Cu layer can be selected from a combination of various widths, and the barrier formed thereby is applied with a heat treatment to measure the variation of the resistance. In a structure of a single Cu layer or a single CuMn layer, the resistance is too high to measure after the temperature exceeds 600° C. Nevertheless, there is better thermal stability in a complex structure, and the resistance is measureable after the temperature exceeds 600° C. These prove that there is better thermal stability and lower resistance in the Cu/CuMn structure.

Preferably, the range of the thickness of the CuMn layer is 25˜70 nm and the range of the thickness of the Cu layer is 10˜50 nm when the percentage of Mn in the CuMn layer 106 is in a range of 1%˜10%.

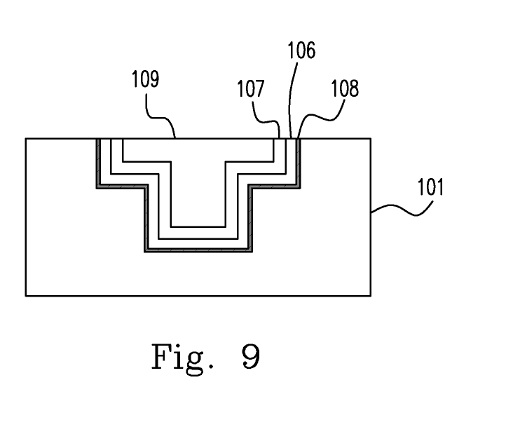

Please refer to FIGS. 8-9 disclosing an embodiment of a copper metallization of the present invention. A copper filling layer 109 is deposited on the Cu layer 107, and a redundant portion above the substrate 101 is subsequently removed by a polishing scheme.

The deposition methods for forming the copper filling layer 109 include sputtering, CVD, MOCVD, PECVD, deposition, sublimation, ECR-PECVD and a combination thereof.

Preferably, the copper filling layer 109 can be deposited by electro-copper plating (ECP). Because the Cu layer 107 can be a seed layer of the copper filling layer 109, the efficiency of ECP is thereby enhanced.

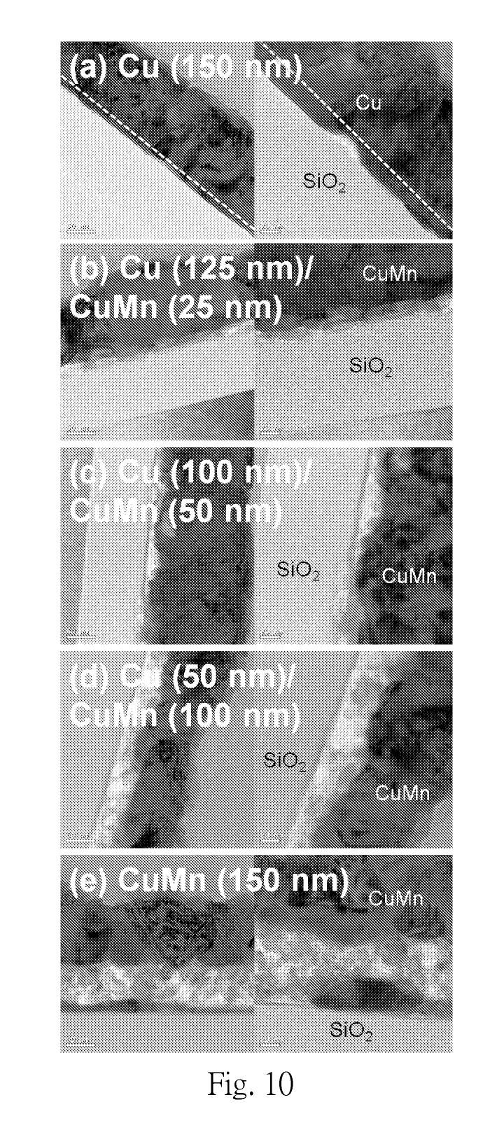

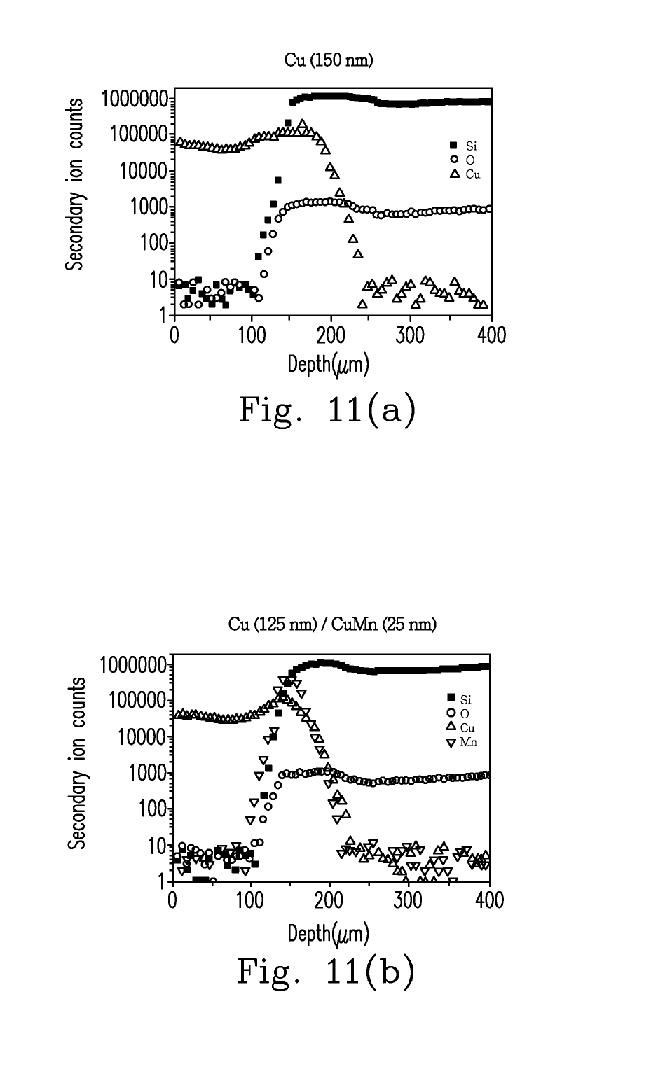

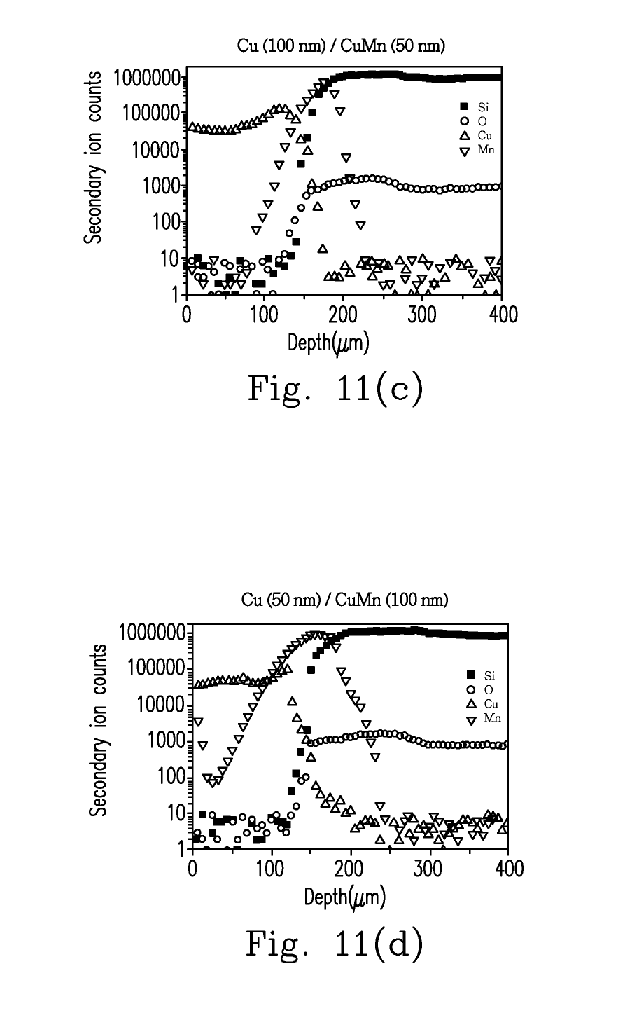

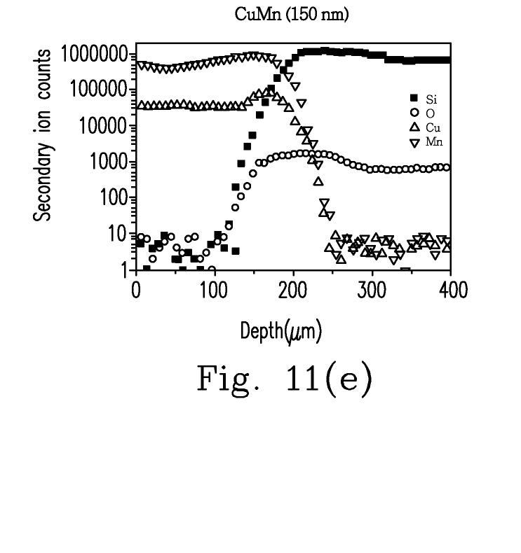

Please refer to FIGS. 10a-11e disclosing pictures of the barrier effect created by the bi-layer structure of the present invention. The diffusion of the annealed Mn atoms can be observed in FIGS. 10a to 10e. FIG. 10a shows a pure Cu thin film, and the Cu atoms diffused into the oxide layer after annealing. As show in FIGS. 10b-10c, it is easier for Mn atoms to diffuse whithin the interface to form a barrier because of the Cu/CuMn structure. AS shown in FIG. 10d, the thin film is in an uneven state because the upper copper film is too thin to stop the Mn atoms from diffusing to the surface. FIG. 10e shows that only a single layer of CuMn thin film is applied after annealing. There are Mn atoms within the interface and surface while the Cu atoms entered the dielectric layer, and thus this structure is unable to stop the Cu atoms from diffusing.

In FIGS. 11a-11e, the depth profile analysis charts correspond to FIGS. 10a-10e illustrating that the bi-layer structures are able to stop the Cu atoms from diffusing into the dielectric layer after annealing, and there are signals of Cu atoms in the oxide layer of the single Cu layer or the single CuMn layer after annealing. Thus it is proved that the bi-layer structures are able to drive Mn atoms to diffuse within the interface to form barriers more quickly and easily and avoid remaining in the lead.

Further embodiments are disclosed as follows.

### Embodiment 1

A method for fabricating a semiconductor structure including providing a substrate; forming a trench in the substrate; conformably forming a copper-manganese alloy layer on the trench; conformably forming a copper metal layer on the copper-manganese alloy; and annealing the copper-manganese alloy layer and the copper metal layer to form a barrier.

### Embodiment 2

In the method according to Embodiment 1, the substrate is one of a silicon dioxide and a silicon wafer.

### Embodiment 3

In the fabricating method according to Embodiment 1 or 2, a range of a thickness of the copper-manganese alloy layer is 25˜70 nm and a range of a thickness of the copper metal layer is 10˜50 nm when a percentage of Mn in the copper-manganese alloy layer is in a range of 1%˜10%.

### Embodiment 4

In the fabricating method according to any of the Embodiments 2-3, a thickness of the copper-manganese alloy layer and the copper metal layer is less than 150 nm.

### Embodiment 5

In the fabricating method according to any of the Embodiments 2-4, a thickness of the copper metal layer is larger than 50 nm.

### Embodiment 6

In the fabricating method according to any of the Embodiments 2-5, the fabricating method further includes forming a conductive material on the copper metal layer for filling the trench.

### Embodiment 7

In the fabricating method according to any of the Embodiments 2-6, the copper-manganese alloy layer is a copper-manganese thin film formed on the trench by a vacuum coating scheme.

### Embodiment 8

In the fabricating method according to any of the Embodiments 2-7, the copper metal layer is a pure copper thin film formed on the copper-manganese alloy layer by a plating method.

### Embodiment 9

In the fabricating method according to any of the Embodiments 2-8, the fabricating method further includes polishing the copper metal layer conformably formed on the copper-manganese alloy layer for a planarization thereof.

### Embodiment 10

A semiconductor structure, including a substrate; an alloy layer having a first metal formed on the substrate; a metal layer having a second metal formed on the alloy layer; and a barrier formed between the alloy layer and the metal layer.

### Embodiment 11

In the semiconductor structure according to Embodiment 10, the barrier is one of a copper-manganese alloy and a copper alloy with a ruthenium nitride doped.

### Embodiment 12

In the semiconductor structure according to Embodiment 10 or 11, the semiconductor structure further includes a trench conformably formed in the substrate to contain the alloy layer having the first metal.

### Embodiment 13

In the semiconductor structure according to Embodiments 11-12, the trench is a T-shaped trench formed by one of a lithography scheme and an etching scheme.

### Embodiment 14

In the semiconductor structure according to Embodiments 11-13, the semiconductor structure further includes a middle layer conformably formed on the trench

### Embodiment 15

In the semiconductor structure according to Embodiments 11-14, the alloy layer is formed by a deposition method being one selected from a group consisting of sputtering, CVD, MOCVD, PECVD, deposition, sublimation, ECR-PECVD and a combination thereof.

### Embodiment 16

In the semiconductor structure according to Embodiments 11-15, the semiconductor structure further includes a resistance which is measureable after the semiconductor structure has a temperature exceeding 600° C.

### Embodiment 17

In the semiconductor structure according to Embodiments 11-16, the second metal is one selected from a group consisting of a gold, a platinum, a silver, an manganese and a copper.

### Embodiment 18

In the semiconductor structure according to Embodiments 11-17, the first metal is one selected from a group consisting of a gold, a platinum, a silver, an manganese and a copper

### Embodiment 19

In the semiconductor structure according to Embodiments 11-18, the first metal is a transition metal.

### Embodiment 20

A barrier structure, including an alloy layer having a first metal, wherein the first metal is a transition metal; and a pure first metal layer conformably formed on the alloy layer.

While the invention has been described in terms of what are presently considered to be the most practical and preferred embodiments, it is to be understood that the invention need not be limited to the disclosed embodiments. On the contrary, it is intended to cover various modifications and similar arrangements included within the spirit and scope of the appended claims, which are to be accorded with the broadest interpretation so as to encompass all such modifications and similar structures. Therefore, the above description and illustration should not be taken as limiting the scope of the present invention which is defined by the appended claims.

What is claimed is:

1. A method for fabricating a semiconductor structure, comprising:
providing a substrate;
forming a trench in the substrate;
conformably forming a copper-manganese alloy layer on the trench;
conformably forming a copper metal layer on the copper-manganese alloy; and
annealing the copper-manganese alloy layer and the copper metal layer to form a barrier.

2. The method according to claim 1, wherein the substrate is one of a silicon dioxide and a silicon wafer.

3. The method according to claim 1, wherein the copper-manganese alloy layer has a thickness in a range of 25˜70 nm and the copper metal layer has a thickness in a range of 10˜50 nm and the percentage of Mn in the copper-manganese alloy layer is in a range of 1%˜10%.

4. The method according to claim 1, wherein the copper-manganese alloy layer and the copper metal layer have a total thickness less than or equal to 150 nm.

5. The method according to claim 1, wherein the copper metal layer has a thickness larger than 50 nm.

6. The method according to claim 1, further comprising forming a conductive material on the copper metal layer to fill the trench.

7. The method according to claim 1, wherein the copper-manganese alloy layer is a copper-manganese thin film formed on the trench by a vacuum coating scheme.

8. The method according to claim 1, wherein the copper metal layer is a pure copper thin film formed on the copper-manganese alloy layer by a plating method.

9. The method according to claim 1, further comprising polishing the copper metal layer conformably formed on the copper-manganese alloy layer for adjusting a planarization thereof.

10. A semiconductor structure, comprising:
a substrate;
an alloy layer having a first metal formed on the substrate;
a metal layer having a second metal formed on the alloy layer; and
a barrier formed between the alloy layer and the metal layer.

11. The structure according to claim 10, wherein the barrier is one of a copper-manganese alloy and a copper alloy with a ruthenium nitride doped therein.

12. The semiconductor structure according to claim 10, further comprising a trench conformably formed in the substrate to contain the alloy layer having the first metal.

13. The structure according to claim 12, wherein the trench is a T-shaped trench formed by one of a lithography scheme and an etching scheme.

14. The structure according to claim 12, further comprising a middle layer conformably formed on the trench.

15. The structure according to claim 10, wherein the alloy layer is formed by a deposition method being one selected from a group consisting of sputtering, CVD, MOCVD, PECVD, deposition, sublimation, ECR-PECVD and a combination thereof.

16. The structure according to claim 10, further comprising a resistance which is measureable after the semiconductor structure has a temperature exceeding 600° C.

17. The structure according to claim 10, wherein the second metal is one selected from a group consisting of a gold, a platinum, a silver, an manganese and a copper.

18. The structure according to claim 10, wherein the first metal is one selected from a group consisting of a gold, a platinum, a silver, an manganese and a copper.

19. The structure according to claim 10, wherein the first metal is a transition metal.

20. A barrier structure, comprising:
an alloy layer having a first metal, wherein the first metal is a transition metal; and
a pure first metal layer conformably formed on the alloy layer.
